(19) United States
(12) Patent Application Publication
(10) Pub. No.: US 2026/0047173 A1
(43) Pub. Date: Feb. 12, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yun-Feng KAO, New Taipei City (TW); Ming-Yen CHUANG, Hsinchu City (TW); Katherine H. CHIANG, New Taipei City (TW)

(21) Appl. No.: 18/796,612

(22) Filed: Aug. 7, 2024

(51) Int. Cl. H01L 29/45; H01L 21/443; H01L 29/66; H01L 29/786

(52) U.S. Cl. CPC H10D 64/62; H01L 21/443; H10D 30/6755; H10D 99/00

(57) ABSTRACT

A transistor structure (e.g., a backend transistor structure in an interconnect layer of a semiconductor device) is formed to include an oxide-semiconductor channel layer having a high electron concentration oxide-semiconductor material. The high electron concentration oxide-semiconductor material enables a low threshold voltage and a low channel resistance to be achieved for the oxide-semiconductor channel layer, which enables a high on current to be achieved for the transistor structure. To provide channel control over the oxide-semiconductor channel layer, an oxide-semiconductor barrier layer is included between the source/drain electrodes of the transistor structure and the oxide-semiconductor channel layer. The oxide-semiconductor barrier layer includes a low electron concentration oxide-semiconductor material, which enables increased control over the conductivity of the oxide-semiconductor channel layer to be achieved, which enables a low off current leakage to be achieved for the transistor structure.

### BACKGROUND

In some cases, a transistor may be formed in an interconnect layer of a semiconductor device. The interconnect layer is sometimes referred to as a backend region or back end of line (BEOL) region of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A and 2B are diagrams of an example implementation of a transistor structure described herein.

FIGS. 3A-3F are diagrams of an example implementation of forming a semiconductor device described herein.

FIGS. 4A-4H are diagrams of an example implementation of forming a transistor structure described herein.

FIG. 5 is a diagram of an example implementation of a transistor structure described herein.

FIG. 6 is a diagram of an example implementation of a transistor structure described herein.

FIG. 7 is a diagram of an example implementation of a transistor structure described herein.

FIG. 8 is a flowchart of an example process associated with forming a backend transistor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Forming a transistor in an interconnect layer (e.g., a back end of line (BEOL) region or backend region) of a semiconductor device often involves the use of different materials and/or structures than those used in transistors formed in a device layer (e.g., a front end of line (FEOL) region) of the semiconductor device. The transistors in the device layer can be formed in a semiconductor substrate of the semiconductor device, whereas transistors formed in the interconnect layer of the semiconductor device are typically formed in a dielectric layer in the semiconductor device. Thus, oxide-semiconductor materials are often used in the channel layers of the transistors in the interconnect layer because oxide-semiconductor materials offer better integration with the dielectric materials used in the interconnect layer, compared to semiconductor materials used in the channel layers of the transistors in the device layer. In particular, oxide-semiconductor materials may be processed at lower temperatures, may achieve greater nucleation uniformity on dielectric materials, and/or may achieve higher crystallinity on dielectric materials than semiconductor materials such as silicon (Si).

In some cases, the material of an oxide-semiconductor channel layer may be formed of a low electron concentration material to achieve low off current (I_{off}) leakage for a transistor in an interconnect layer of a semiconductor device. However, low electron concentration material sacrifices charge carrier mobility in the oxide-semiconductor channel layer, resulting in high channel resistance, low on current (Iₒₙ), and/or a high threshold voltage (Vₜ) for the transistor.

In some implementations described herein, a transistor structure (e.g., a backend transistor structure in an interconnect layer of a semiconductor device) is formed to include an oxide-semiconductor channel layer having a high electron concentration oxide-semiconductor material. The high electron concentration oxide-semiconductor material enables a low threshold voltage and a low channel resistance to be achieved for the oxide-semiconductor channel layer, which enables a high on current to be achieved for the transistor structure. To provide channel control over the oxide-semiconductor channel layer, an oxide-semiconductor barrier layer is included between the source/drain electrodes of the transistor structure and the oxide-semiconductor channel layer. The oxide-semiconductor barrier layer includes a low electron concentration oxide-semiconductor material, which enables increased control over the conductivity of the oxide-semiconductor channel layer to be achieved, which enables a low off current leakage to be achieved for the transistor structure.

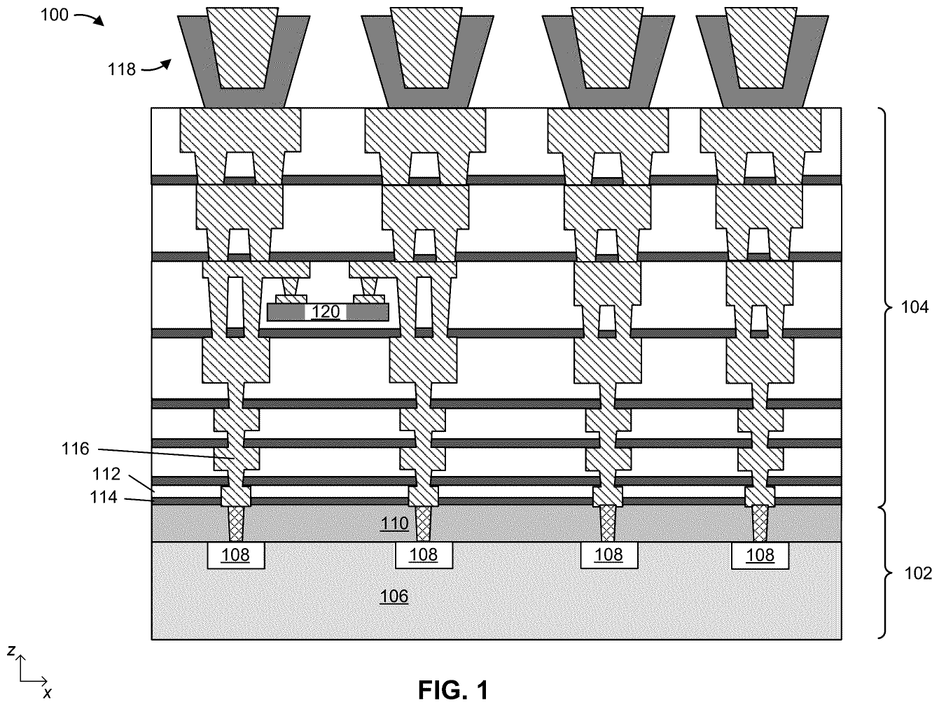

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), and/or another type of semiconductor device.

As shown in FIG. 1, the semiconductor device 100 may include a device layer 102 and an interconnect layer 104 above the device layer 102 in a z-direction in the semiconductor device 100. The device layer 102 may also be referred to as a frontend region or FEOL region of the semiconductor device 100. The interconnect layer 104 may also be referred to as a backend region or BEOL region of the semiconductor device 100.

The device layer 102 includes a substrate 106. The substrate 106 may correspond to a portion of a semiconductor wafer on which the semiconductor device 100 is formed. The substrate 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 106 may extend in an x-direction and/or in a y-direction in the semiconductor device 100.

Semiconductor devices 108 may be included in and/or on the substrate 106 in the device layer 102 of the semiconductor device 100. The semiconductor devices 108 include frontend transistor structures (e.g., frontend planar transistor structures, frontend fin field effect transistor (finFET) structures, frontend gate all around (GAA) transistor structures), pixel sensors, capacitors, resistors, inductors, photodetectors, transceivers, transmitters, receives, optical circuits, and/or other types of frontend semiconductor devices. Frontend semiconductor devices refer to the semiconductor devices that are formed in the device layer 102 (e.g., in and/or on the substrate 106) of the semiconductor device 100.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the semiconductor devices 108 to be selectively etched or protected from etching, and/or to electrically isolate the semiconductor devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in a y-direction in the semiconductor device 100.

The interconnect layer 104 of the semiconductor device 100 is included above the substrate 106 and above the semiconductor devices 108 in the z-direction in the semiconductor device 100. The interconnect layer 104 includes a plurality of dielectric layers (e.g., backend dielectric layers) that are arranged in a direction (e.g., the z-direction) that is approximately perpendicular to the substrate 106. The dielectric layers may include ILD layers 112 and ESLs 114 that are arranged in an alternating manner in the z-direction. The ILD layers 112 and the ESLs 114 may extend in the x-direction and/or in the y-direction in the semiconductor device 100.

The ILD layers 112 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 112 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 114 may each include a silicon nitride (SiₓN_{y}), silicon carbide (SIC), silicon oxynitride (SiON), and/or another suitable dielectric material. In some implementations, an ILD layer 112 and an ESL 114 include different dielectric materials to provide etch selectivity to enable various structures to be formed in the interconnect layer 104.

The interconnect layer 104 includes a plurality of conductive structures 116. One or more of the conductive structures 116 are electrically coupled and/or physically coupled with one or more of the semiconductor devices 108 in the device layer 102. The conductive structures 116 provide electrical routing that enables signals and/or power to be provided to and/or from the semiconductor devices 108. The conductive structures 116 may include a combination of vias, trenches, contacts, plugs, interconnects, metallization layers, conductive traces, and/or other types of conductive structures. The conductive structures 116 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the conductive structures 116 and the ILD layers 112, and/or between the conductive structures 116 and the ESLs 114. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 116 of the interconnect layer 104 may be arranged in in a vertical manner (e.g., in the z-direction). In other words, a plurality of stacked conductive structures 116 extend between the device layer 102 and connection structures 118 above the interconnect layer 104 to facilitate electrical signals and/or power to be routed between the device layer 102 and the connection structures 118. The plurality of stacked conductive structures 116 may be referred to as M-layers. For example, a metal-0 (M0) layer may located at the bottom of the interconnect layer 104 and may be directly coupled with the device layer 102 (e.g., with the contacts or vias of the semiconductor devices 108 in the device layer 102), a metal-1 layer (M1) layer may be located above the M0 layer in the interconnect layer 104, a metal-2 layer (M2) layer may be located above the M1 layer, and so on. Additionally, via layers may be included between vertically arranged M-layers. For example, a via-1 (V1) layer may be included between the M1 layer and the M2 layer to interconnect the M1 layer and the M2 layer, a via-2 (V2) layer may be included between the M2 layer and the M3 layer to interconnect the M2 layer and the M3 layer, and so on.

The connection structures 118 include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. The connection structures 118 enable the semiconductor device 100 to be attached to a semiconductor device package substrate (e.g., an interposer, a redistribution layer (RDL) structure, a printed circuit board (PCB)) and/or to another semiconductor device.

One or more semiconductor devices are also included in the interconnect layer 104 of the semiconductor device 100. For example, a transistor structure 120 is included in an ILD layer 112 of the interconnect layer 104. The transistor structure 120 may be referred to as a backend transistor structure or BEOL transistor structure in that the transistor structure 120 is included in the interconnect layer 104 (e.g., the backend region or BEOL region) of the semiconductor device 100 as opposed to the device layer 102 (e.g., the frontend region or FEOL region) of the semiconductor device 100. The transistor structure 120 is electrically coupled and/or physically coupled with one or more conductive structures 116 in the interconnect layer 104.

In some implementations, the transistor structure 120 may be electrically coupled to a capacitor in the interconnect layer 104. The combination of the transistor structure 120 and the capacitor may correspond to a memory cell (e.g., a dynamic random access memory (DRAM) cell) in the interconnect layer 104. In some implementations, the transistor structure 120 includes a memory layer (e.g., a ferroelectric memory layer, a resistive memory layer, a floating memory layer) such that the transistor structure 120 corresponds to a transistor-based memory cell (e.g., a ferroelectric field effect transistor (FeFET) memory cell, floating gate transistor memory cell).

As indicated above, FIG. 1 is provided as an example. Other examples may differ from what is described with regard to FIG. 1.

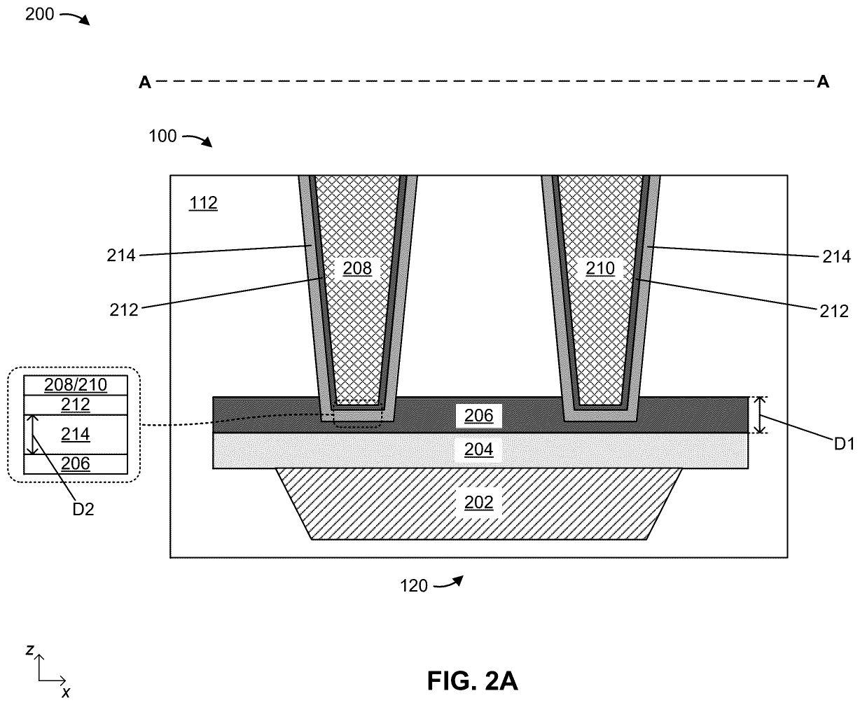

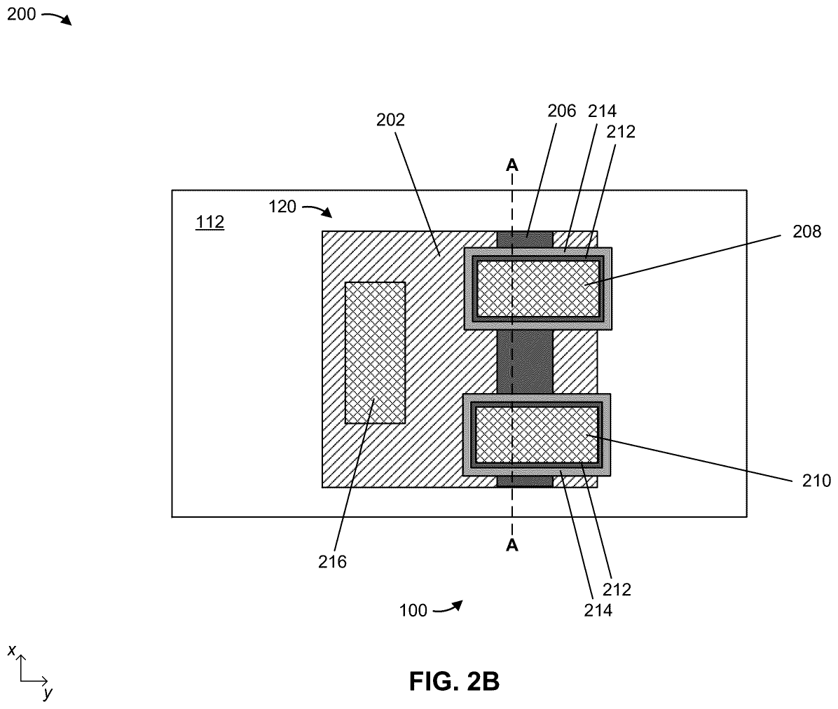

FIGS. 2A and 2B are diagrams of an example implementation 200 of a transistor structure 120 described herein. As described in connection with FIG. 1, the transistor structure 120 may be referred to as a backend transistor structure or a BEOL transistor structure in that the transistor structure 120 is included in an ILD layer 112 in the interconnect layer 104 of the semiconductor device 100. The transistor structure 120 may also be referred to as a thin-film transistor (TFT) in that one or more layers (e.g., a gate dielectric layer, a channel layer) of the transistor structure 120 are formed as thin films using thin-film deposition techniques. The transistor structure 120 includes an oxide-semiconductor channel layer, which enables the manufacturing process for the transistor structure 120 to be integrated into the manufacturing process for the interconnect layer 104.

FIG. 2A illustrates a cross-section view of the transistor structure 120. The transistor structure 120 may include a gate electrode 202. The gate electrode 202 may be referred to as a bottom gate electrode or a buried gate electrode in that the gate electrode 202 is located at the bottom of the transistor structure 120. The gate electrode 202 may be electrically coupled with a gate contact, as shown in FIG. 2B. The gate electrode 202 may include one or more electrically conductive metal materials. Examples of such electrically conductive metal-containing materials include platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), gold (Au), silver (Ag), palladium (Pd), copper (Cu), aluminum (Al), ruthenium (Ru), and/or an alloy thereof, among other examples. Additionally and/or alternatively, the gate electrode 202 may include polysilicon, doped silicon (Si), and/or another suitable material.

The transistor structure 120 includes a gate dielectric layer 204. The gate dielectric layer 204 may be included over and/or on the gate electrode 202. The gate dielectric layer 204 may be a high dielectric constant (high-k) gate dielectric layer in that the gate dielectric layer 204 may include one or more high-k dielectric materials that have a dielectric constant greater than the dielectric constant of silicon dioxide (SiO₂—approximately 3.9 dielectric constant). Examples of such high-k dielectric materials include metal-oxide materials having a dielectric constant that is greater than or approximately equal to 9, such as silicon nitride (SiₓN_{y} such as Si₃N₄), silicon oxynitride (SiON), hafnium oxide (HfOₓ such as HfO₂), aluminum oxide (AlₓO_{y} such as Al₂O₃), titanium oxide (TiO), and/or zirconium oxide (ZrOₓ such as ZrO₂), among other examples. In some implementations, the gate dielectric layer 204 includes an oxide-containing dielectric material having a dielectric constant that is greater than or approximately equal to 6. For example, the gate dielectric layer 204 may include an oxide material that includes two or more of hafnium (Hf), titanium (Ti), lanthanum (La), silicon (Si), tantalum (Ta), aluminum (Al), and/or zirconium (Zr). Examples of such dielectric materials include hafnium titanium oxide (HfₓTi_{y}O_{z}), hafnium tantalum oxide (HfₓTa_{y}O_{z}), hafnium lanthanum oxide (HfₓLa_{y}O_{z}), hafnium silicon oxide (HfₓSi_{y}O_{z}), hafnium silicon oxynitride (HfSiON), hafnium zirconium oxide (HfₓZr_{y}O_{z}), zirconium silicate (ZrSiOₓ such as ZrSiO₄), a zirconium aluminate alloy (ZrO₂—Al₂O₃), and/or a hafnium dioxide-alumina alloy (HfO₂—Al₂O₃), among other examples. Additionally and/or alternatively, the gate dielectric layer 204 may include a silicon oxide (SiOₓ such as SiO₂) and/or another low dielectric constant (low-k) dielectric material having a dielectric constant less than or approximately equal to the dielectric constant of silicon dioxide.

In some implementations, the gate dielectric layer 204 may function as a memory layer of the transistor structure 120. For example, the gate dielectric layer 204 may include a ferroelectric material for which an electric polarization can be switched between two or more discrete polarization states by applying an external electric field to the gate dielectric layer 204. The polarization states correspond to different values for data stored in the transistor structure 120. Examples of such ferroelectric materials include aluminum scandium nitride (e.g., AlScN), PBT (e.g., PbZrO₃), PZT (e.g., Pb[ZrₓTi₁₋ₓ]O₃, (0≤x≤1)), PLZT (e.g., Pb₁₋ₓLaₓZr_{1-y}Ti_{y}O₃), barium titanate (e.g., BaTiO₃), lead titanate (e.g., PbTiO₃), lead metaniobate (e.g., PbNb₂O₆), lithium niobate (e.g., LiNbO₃), lithium tantalate (e.g., LiTaO₃), PMN (e.g., PbMg₁₋₃Nb_{2/3}O₃), PST (e.g., PbSc_{1/2}Ta_{1/2}O₃), SBT (e.g., SrBi₂Ta₂O₉), BNT (e.g., Bi_{1/2}Na_{1/2}TiO₃), and/or combinations thereof, among other examples. In some implementations, the ferroelectric material may include dopants such as scandium (Sc), lanthanum (La), calcium (Ca), barium (Ba), yttrium (Y), strontium (Sr), zirconium (Zr), silicon (Si), aluminum (Al), scandium (Sc), indium (In), and/or gadolinium (Gd), among other examples. For example, the ferroelectric material may include hafnium oxide doped with zirconium (e.g., Zr:HfO₂), hafnium oxide doped with silicon (e.g., Si:HfO₂), hafnium oxide doped with lanthanum (e.g., La:HfO₂), hafnium oxide doped with aluminum (e.g., Al:HfO₂), hafnium oxide doped with tantalum (Ta:HfO₂), hafnium oxide doped with scandium (e.g., Sc:HfO₂), hafnium oxide doped with yttrium (e.g., Y:HfO₂), hafnium oxide doped with strontium (e.g., Sr:HfO₂), hafnium oxide doped with indium (e.g., In:HfO₂), and/or hafnium oxide doped with gadolinium (e.g., Gd:HfO₂), among other examples.

The transistor structure 120 includes an oxide-semiconductor channel layer 206 above the gate dielectric layer 204. In some implementations, a capping layer (not shown) may be included on the oxide-semiconductor channel layer 206 or may be omitted. The oxide-semiconductor channel layer 206 includes one or more oxide-semiconductor materials. Examples of such oxide-semiconductor materials include tin oxide (e.g., SnO or SnO₂), indium tin oxide (InSnO), indium gallium zinc oxide (InGaZnO or IGZO), indium gallium oxide (InGaO or IGO), indium zinc oxide (InZnO or IZO), indium tungsten oxide (InWO or IWO), zinc oxide (ZnO), gallium oxide (GaOₓ), indium oxide (InOₓ), and/or aluminum zinc oxide (AlZnO or AZO), among other examples.

In some implementations, the oxide-semiconductor channel layer 206 includes an oxide-semiconductor material that includes indium (In), gallium (Ga), zinc (Zn), and one or more additional metals such as titanium (Ti), aluminum (Al), silver (Ag), vanadium (V), scandium (Sc), tungsten (W), tin (Sn), cerium (Ce), among other examples. For example, the oxide-semiconductor channel layer 206 may include InₓGa_{y}Zn_{z}MO, where M corresponds to one or more of the above-described metals, where 0≤x≤1, where 0≤y≤1, and where 0≤z≤1.

In some implementations, the oxide-semiconductor channel layer 206 is alternatively implemented by a metal channel layer that includes a low-conductivity metal such as titanium nitride (TiN), tantalum nitride (TaN), and/or titanium (Ti), among other examples.

The oxide-semiconductor material of the oxide-semiconductor channel layer 206 (or alternatively, the metal material of the metal channel layer) may have a high electron concentration (which may also be associated with the number of doping (N_{d}) for the oxide-semiconductor channel layer 206). The high electron concentration (e.g., greater than approximately 1×10¹⁷ electrons per cubic centimeter) in the material of the oxide-semiconductor channel layer 206 enables the oxide-semiconductor channel layer 206 to have high carrier mobility for increased conductivity and low electrical resistance. In this way, the high electron concentration enables a high on current (Iₒₙ) to be achieved in the oxide-semiconductor channel layer 206. In some implementations, the electron concentration in the oxide-semiconductor channel layer 206 is greater than approximately 1×10¹⁸ electrons per cubic centimeter and less than or approximately equal to 1×10²⁰ electrons per cubic centimeter. In some implementations, the electron concentration in the oxide-semiconductor channel layer 206 is greater than approximately 1×10²⁰ electrons per cubic centimeter. However, other values and ranges for the electron concentration in the oxide-semiconductor channel layer 206 are within the scope of the present disclosure.

The oxide-semiconductor channel layer 206 may be a thin-film layer having a z-direction thickness (indicated in FIG. 2A as a dimension D1) that is included in a range of approximately 1 nanometer to approximately 20 nanometers. If the z-direction thickness of the oxide-semiconductor channel layer 206 is less than approximately 1 nanometer, voids may occur in the oxide-semiconductor channel layer 206 during formation of the oxide-semiconductor channel layer 206, and/or channel resistance may be high for the oxide-semiconductor channel layer 206. If the z-direction thickness of the oxide-semiconductor channel layer 206 is greater than approximately 20 nanometers, the top of the oxide-semiconductor channel layer 206 may be too far away from the gate electrode 202, resulting in reduced control over the conductivity of the oxide-semiconductor channel layer 206 at the top of the oxide-semiconductor channel layer 206. If the z-direction thickness of the oxide-semiconductor channel layer 206 is included in the range of approximately 1 nanometer to approximately 20 nanometers, a low channel resistance may be achieved for the oxide-semiconductor channel layer 206 while enabling sufficient control over the conductivity of the oxide-semiconductor channel layer 206. However, other values, and ranges other than approximately 1 nanometer to approximately 20 nanometers, for the z-direction thickness of the oxide-semiconductor channel layer 206 are within the scope of the present disclosure.

The electrical conductivity of the oxide-semiconductor channel layer 206 is capable of being selectively controlled by the gate electrode 202 to selectively enable an electrical current to flow between source/drain electrodes 208 and 210 of the transistor structure 120. When a voltage is applied to the gate electrode 202, the oxide-semiconductor channel layer 206 may become electrically conductive, thereby enabling the electrical current to flow between source/drain electrodes 208 and 210. Conversely, when the voltage is removed from the gate electrode 202, the oxide-semiconductor channel layer 206 may become electrically non-conductive, thereby preventing the electrical current from flowing between source/drain electrodes 208 and 210.

The source/drain electrodes 208 and 210 may be included above and/or on the oxide-semiconductor channel layer 206. In some implementations, the bottom portions of the source/drain electrodes 208 and 210 are recessed in the oxide-semiconductor channel layer 206. “Source/drain electrode” may refer to a source region or a drain electrode, individually or collectively, dependent upon the context. The source/drain electrodes 208 and 208 may each include one or more electrically conductive metal materials. Examples of such electrically conductive metal-containing materials include platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), gold (Au), silver (Ag), palladium (Pd), copper (Cu), aluminum (Al), ruthenium (Ru), and/or an alloy thereof, among other examples. Additionally and/or alternatively, the source/drain electrodes 208 and 208 may each include polysilicon, doped silicon (Si), and/or another suitable material.

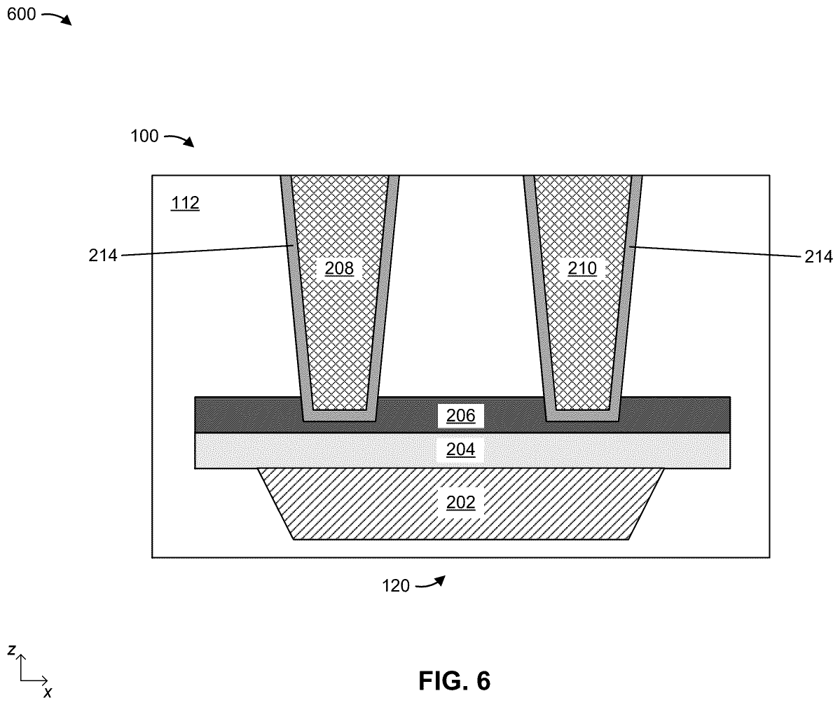

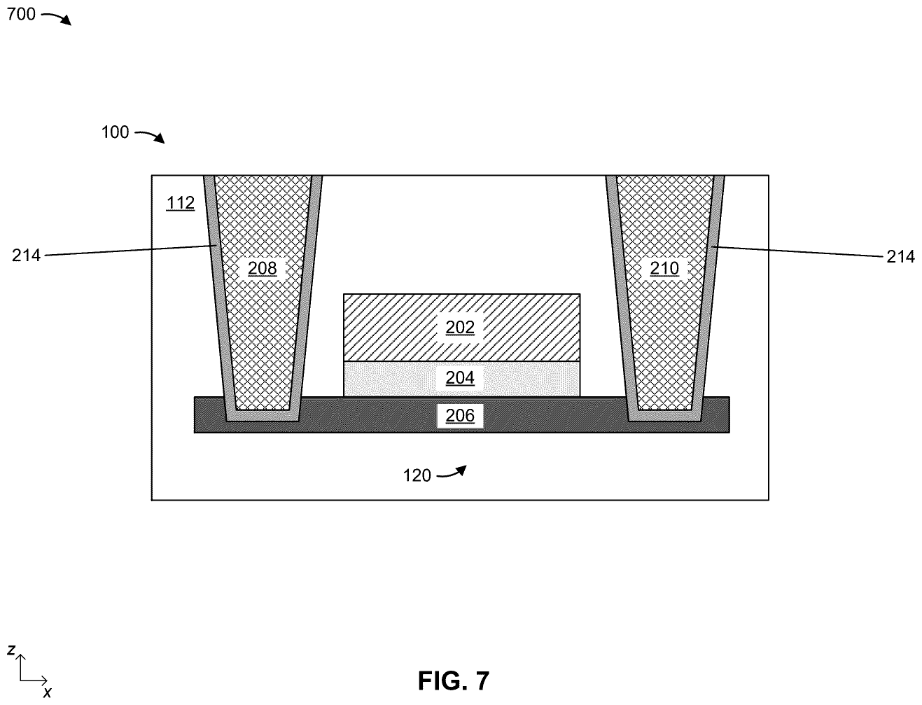

The source/drain electrodes 208 and 210 may each be electrically coupled with a conductive structure 116 in the interconnect layer 104 of the semiconductor device 100. This enables electrical inputs (e.g., voltages, electrical currents) to be applied to the source/drain electrode 208 and/or the source/drain electrode 210, and/or enables the source/drain electrode 208 and/or the source/drain electrode 210 to be electrically grounded. Additionally and/or alternatively, the source/drain electrode 208 and/or 210 may be electrically coupled with a capacitor structure through one or more conductive structures 116 in the interconnect layer 104. As further shown in FIG. 2A, one or more barrier layers may be included on the sidewalls and/or on the bottom surface of the source/drain electrodes 208 and 210. For example, an oxide-semiconductor barrier layer 212 may be included on the sidewalls and on the bottom surfaces of the source/drain electrodes 208 and 210. In some implementations, the oxide-semiconductor barrier layer 212 is included only on the bottom surfaces of the source/drain electrodes 208 and 210. The oxide-semiconductor barrier layer 212 may be in direct contact with the bottom surfaces (and, in some implementations, the sidewalls) of the source/drain electrodes 208 and 210 such that the oxide-semiconductor barrier layer 212 is located between the oxide-semiconductor channel layer 206 and the bottom surfaces of the source/drain electrodes 208 and 210. In some implementations, the oxide-semiconductor barrier layer 212 is omitted from the transistor structure 120, such as in the example implementations illustrated in FIGS. 6 and 7.

As another example, another oxide-semiconductor barrier layer 214 may be included on the sidewalls and on the bottom surfaces of the source/drain electrodes 208 and 210. In some implementations, the oxide-semiconductor barrier layer 214 is included only on the bottom surfaces of the source/drain electrodes 208 and 210. The oxide-semiconductor barrier layer 214 may be in direct contact with the oxide-semiconductor barrier layer 212 such that the oxide-semiconductor barrier layer 212 is between the oxide-semiconductor barrier layer 214 and the source/drain electrodes 208 and 210. Alternatively, in implementations in which the oxide-semiconductor barrier layer 212 is omitted, the oxide-semiconductor barrier layer 214 may be in direct contact with the bottom surfaces (and, in some implementations, the sidewalls) of the source/drain electrodes 208 and 210. The oxide-semiconductor barrier layer 214 is located between the oxide-semiconductor channel layer 206 and the bottom surfaces of the source/drain electrodes 208 and 210.

The oxide-semiconductor barrier layer 212 may be included to reduce the contact resistance of the source/drain electrodes 208 and 210, and may include a high electron concentration (e.g., similar to the electron concentration in the oxide-semiconductor channel layer 206). The oxide-semiconductor barrier layer 214 may be included as the on/off control region for the transistor structure 120, and may include a low electron concentration (e.g., less than the electron concentration in the oxide-semiconductor channel layer 206 and in the oxide-semiconductor barrier layer 212). In other words, the low electron concentration in the oxide-semiconductor barrier layer 214 enables the oxide-semiconductor barrier layer 214 to control the off current (I_{off}) leakage through the oxide-semiconductor channel layer 206. In this way, the low electron concentration in the oxide-semiconductor barrier layer 214 enables low electrical leakage to be achieved for the oxide-semiconductor channel layer 206, while enabling the oxide-semiconductor channel layer 206 to be formed of a high electron concentration material so that a high on current can be achieved in the oxide-semiconductor channel layer 206.

In some implementations, the electron concentration in the oxide-semiconductor barrier layer 214 is included in a range of approximately 5×10¹⁶ electrons per cubic centimeter to approximately 1×10¹⁸ electrons per cubic centimeter. If the electron concentration in the oxide-semiconductor barrier layer 214 is less than approximately 5×10¹⁶ electrons per cubic centimeter, the channel mobility for the transistor structure 120 may be low, leading to a low on current and a high threshold voltage (Vₜ). If the electron concentration in the oxide-semiconductor barrier layer 214 is greater than approximately 1×10¹⁸ electrons per cubic centimeter, the oxide-semiconductor barrier layer 214 may not provide sufficient control over the oxide-semiconductor channel layer 206, resulting in a high off current leakage for the transistor structure 120. If the electron concentration in the oxide-semiconductor barrier layer 214 is included in the range of approximately 5×10¹⁶ electrons per cubic centimeter to approximately 1×10¹⁸ electrons per cubic centimeter, low off current leakage for the transistor structure 120 may be achieved while achieving a high on current and a low threshold voltage (Vₜ). However, other values, and ranges other than approximately 5×10¹⁶ electrons per cubic centimeter to approximately 1×10¹⁸ electrons per cubic centimeter, for the electron concentration in the oxide-semiconductor barrier layer 214, are within the scope of the present disclosure.

As shown in a close-up view in FIG. 2A, the oxide-semiconductor barrier layer 214 may have a thickness indicated in FIG. 2A as dimension D2. In some implementations, the thickness of the oxide-semiconductor barrier layer 214 is included in greater than approximately 0 nanometers and less than approximately 10 nanometers. If portions of the oxide-semiconductor barrier layer 214 have a 0-nanometer thickness, the oxide-semiconductor barrier layer 214 may have voids or other discontinuities that result in an increased off current leakage in the transistor structure 120. If the thickness of the oxide-semiconductor barrier layer 214 is approximately 10 nanometers or greater, the oxide-semiconductor barrier layer 214 may not provide sufficient electrical resistance between the oxide-semiconductor channel layer 206 and the source/drain electrodes 208 and 210, resulting in high off current leakage for the transistor structure 120. If the thickness of the oxide-semiconductor barrier layer 214 is greater than approximately 0 nanometers and less than approximately 10 nanometers, low off current leakage for the transistor structure 120 may be achieved while achieving a high on current. However, other values, and ranges other than greater than approximately 0 nanometers and less than approximately 10 nanometers, for the thickness of the oxide-semiconductor barrier layer 214, are within the scope of the present disclosure.

The high electron concentrations in the oxide-semiconductor channel layer 206 and in the oxide-semiconductor barrier layer 212, and the low electron concentration in the oxide-semiconductor barrier layer 214, may be achieved through various types of doping and/or dopant concentrations in the oxide-semiconductor channel layer 206, the oxide-semiconductor barrier layer 212, and the oxide-semiconductor barrier layer 214.

In some implementations, the hydrogen (H) concentration in the oxide-semiconductor barrier layer 214 may be less than the hydrogen concentrations in the oxide-semiconductor channel layer 206 and the oxide-semiconductor barrier layer 212. The greater hydrogen concentrations in the oxide-semiconductor channel layer 206 and the oxide-semiconductor barrier layer 212 may result in a greater concentration of charge carrier vacancies in the oxide-semiconductor channel layer 206 and in the oxide-semiconductor barrier layer 212, compared to the charge carrier vacancy concentration in the oxide-semiconductor barrier layer 214.

In some implementations, the oxygen (O) concentration in the oxide-semiconductor barrier layer 214 may be greater than the oxygen concentrations in the oxide-semiconductor channel layer 206 and the oxide-semiconductor barrier layer 212. Additionally and/or alternatively, the fluorine (F) concentration in the oxide-semiconductor barrier layer 214 may be greater than the fluorine concentrations in the oxide-semiconductor channel layer 206 and the oxide-semiconductor barrier layer 212. The greater oxygen concentration and/or the greater fluorine concentration in the oxide-semiconductor barrier layer 214 may result in a lesser concentration of charge carrier vacancies in the oxide-semiconductor barrier layer 214 than in the oxide-semiconductor channel layer 206 and in the oxide-semiconductor barrier layer 212.

FIG. 2B illustrates a top view of the transistor structure 120 and a location of the cross-section along line A-A in FIG. 2A. As shown in FIG. 2B, the source/drain electrodes 208 and 210 may extend laterally outward past the sides of the oxide-semiconductor channel layer 206 in the y-direction in the semiconductor device 100. Similarly, the gate electrode 202 may extend laterally outward past the sides of the oxide-semiconductor channel layer 206, as well as laterally outward past the source/drain electrodes 208 and 210, in the y-direction in the semiconductor device 100. This enables a gate contact 216 to be formed on the gate electrode 202.

As further shown in FIG. 2B, the oxide-semiconductor barrier layers 212 and/or 214 may laterally surround the source/drain electrodes 208 and 210. Alternatively, the oxide-semiconductor barrier layers 212 and/or 214 may be included on one or more sides of the source/drain electrodes 208 and/or 210.

As indicated above, FIGS. 2A and 2B are provided as an example. Other examples may differ from what is described with regard to FIGS. 2A and 2B.

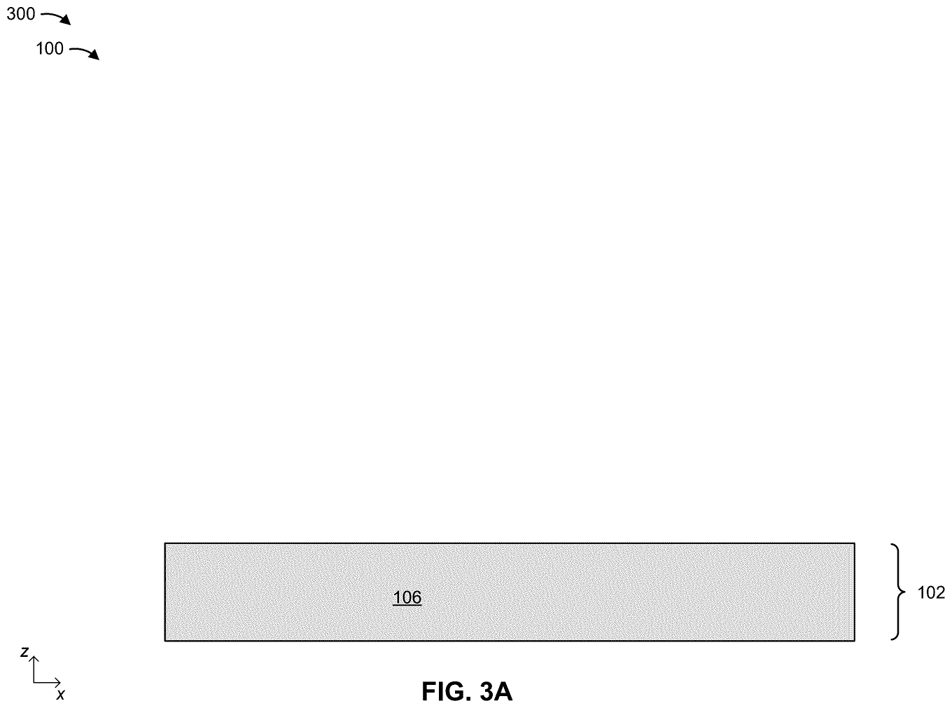

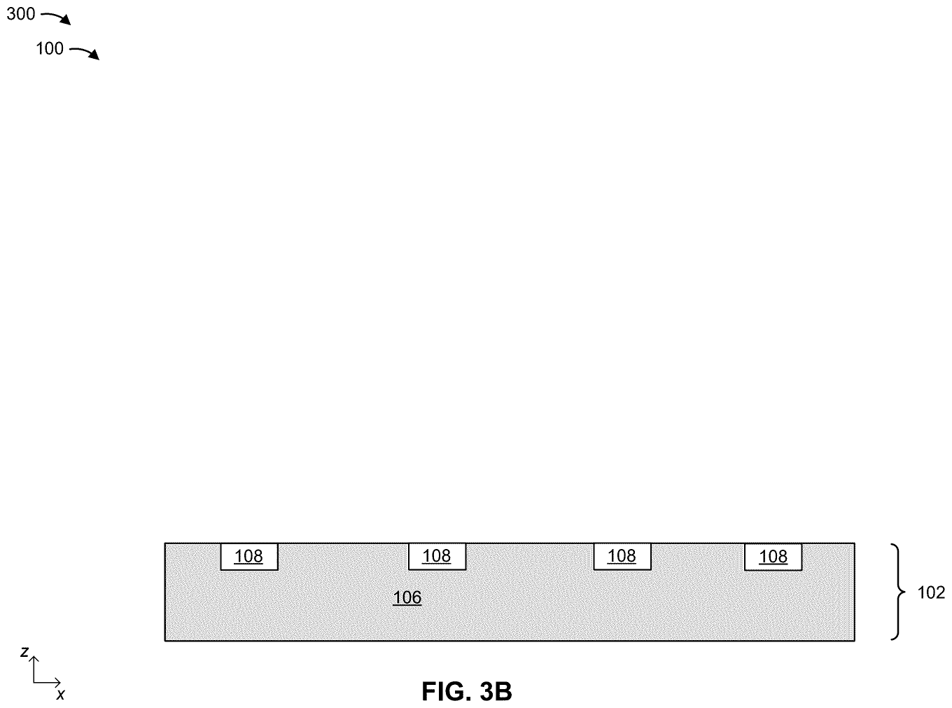

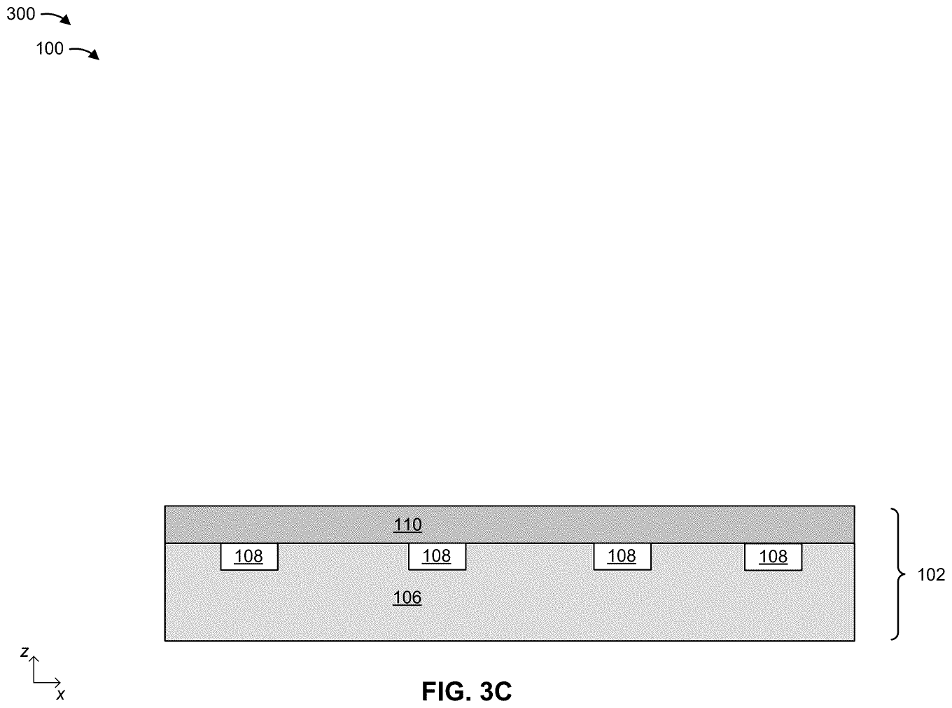

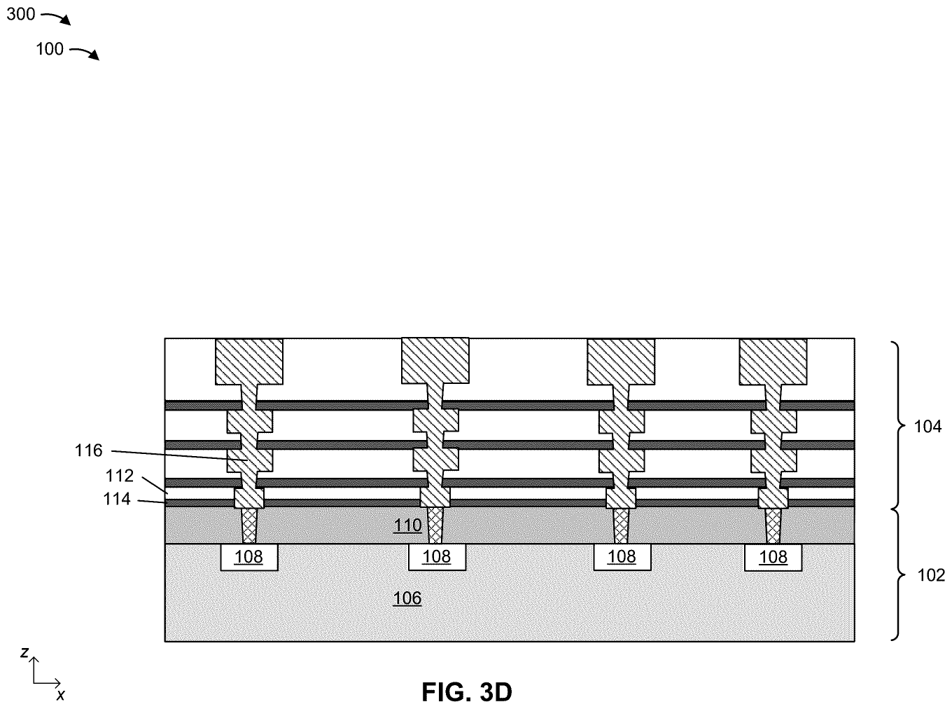

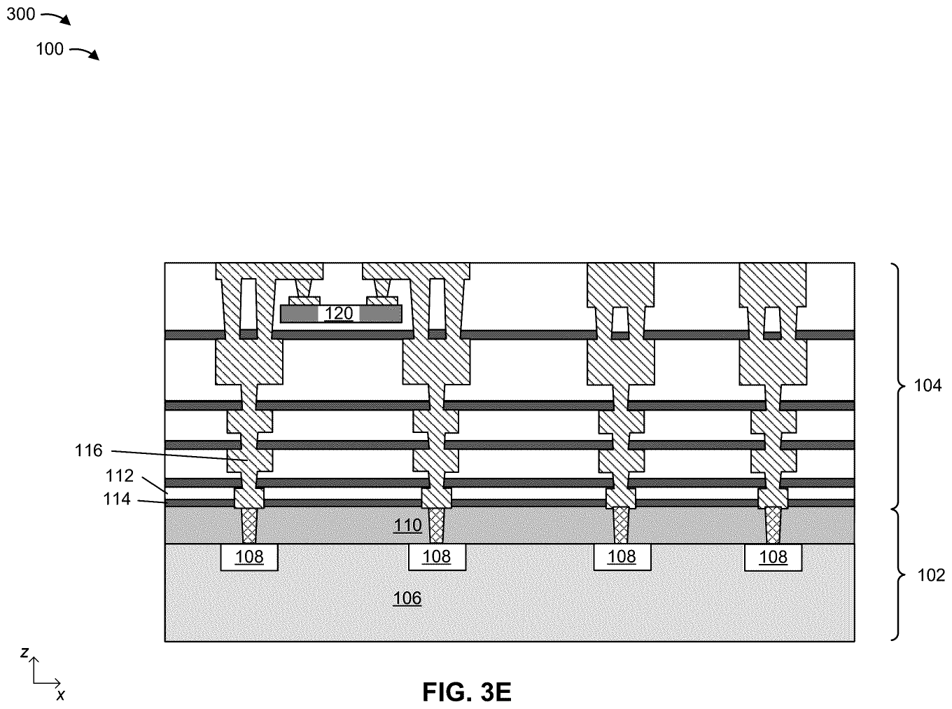

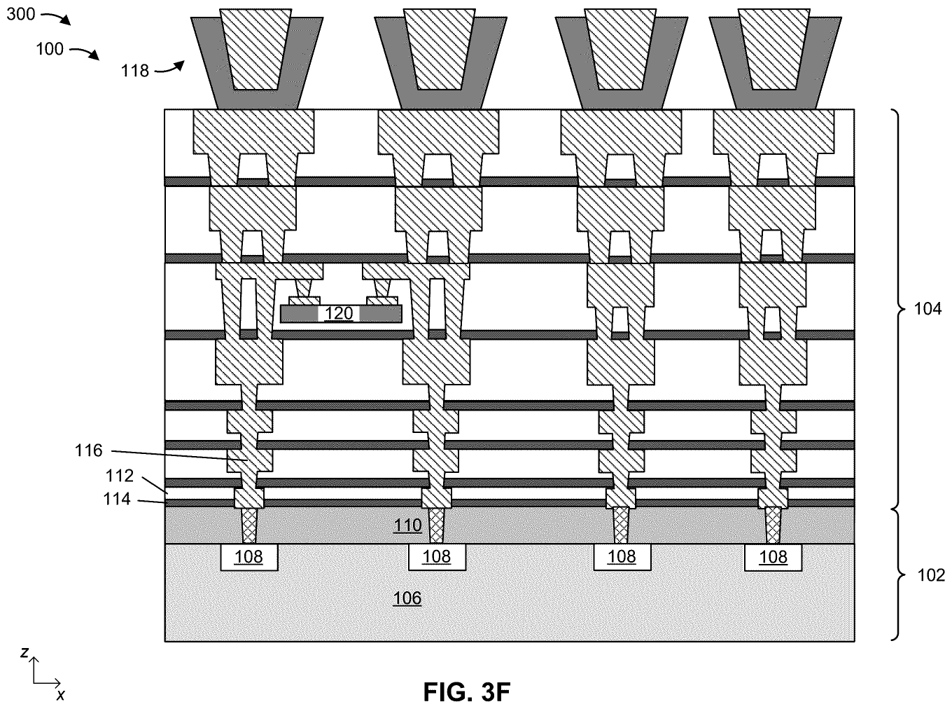

FIGS. 3A-3F are diagrams of an example implementation 300 of forming the semiconductor device 100 described herein. In some implementations, one or more of the semiconductor processing operations described in connection with FIGS. 3A-3F may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 3A, the substrate 106 is provided. The substrate 106 may be provided in the form of a semiconductor wafer such as a silicon (Si) wafer, an SOI wafer, and/or another type of semiconductor work piece.

As shown in FIG. 3B, the semiconductor devices 108 (e.g., the frontend semiconductor devices) may be formed in and/or on the substrate 106 in the device layer 102 of the semiconductor device 100. One or more semiconductor processing tools may be used to form one or more portions of the semiconductor devices 108. For example, a deposition tool may be used to perform various deposition operations to deposit layers and/or structures of the semiconductor devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the semiconductor devices 108. As another example, a planarization tool may be used to planarize portions of the semiconductor devices 108. As another example, a plating tool may be used to deposit metal structures and/or layers of the semiconductor devices 108.

As shown in FIG. 3C, a deposition tool is used to deposit the dielectric layer 110 over and/or on the substrate 106 and over and/or on the semiconductor devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to planarize the dielectric layer 110 after the dielectric layer 110 is deposited.

As shown in FIG. 3D, a first portion of the interconnect layer 104 of the semiconductor device 100 is formed above the dielectric layer 110. One or more deposition tools are used to deposit alternating layers of ILD layers 112 and ESLs 114 in the first portion of the interconnect layer 104 of the semiconductor device 100. In this way, the ILD layers 112 and ESLs 114 may be arranged in the z-direction in the semiconductor device 100. One or more deposition tools may be used to deposit each of the ILD layers 112 and each of the ESLs 114 using a PVD technique, an ALD technique, a CVD technique, an oxidation technique, and/or another suitable deposition technique. In some implementations, a planarization tool may be used to planarize the ILD layers 112 and/or the ESLs 114 after the ILD layers 112 and/or the ESLs 114 are deposited.

As further shown in FIG. 3D, a deposition tool, an exposure tool, a developer tool, an etch tool, a planarization tool, and/or a plating tool are used to perform various operations to form the conductive structures 116 in the first portion of the interconnect layer 104 of the semiconductor device 100. The conductive structures 116 may be included in the ILD layers 112 and/or the ESLs 114, and may be electrically coupled with the semiconductor devices 108 in the device layer 102. In some implementations, the ILD layers 112, the ESLs 114, and the conductive structures 116 may be built up in the z-direction in metallization layers. For example, a first ESL 114 and a first ILD layer 112 may be formed, recesses may be formed in the first ESL 114 and/or in the first ILD layer 112, and first conductive structures 116 (e.g., an M0 metallization layer) may be formed in the recesses. A second ESL 114 and a second ILD layer 112 may be formed above the first ESL 114 and the first ILD layer 112, recesses may be formed in the second ESL 114 and/or in the second ILD layer 112, and second conductive structures 116 (e.g., an M1 metallization layer) may be formed in the recesses. The remaining metallization layers of the first portion of the interconnect layer 104 may be formed in a similar manner. Additionally, via layers may be formed to interconnect the metallization layers in the interconnect layer 104. The via layers may include conductive structures 116 corresponding to vias or interconnects that interconnect two or more metallization layers in the interconnect layer 104.

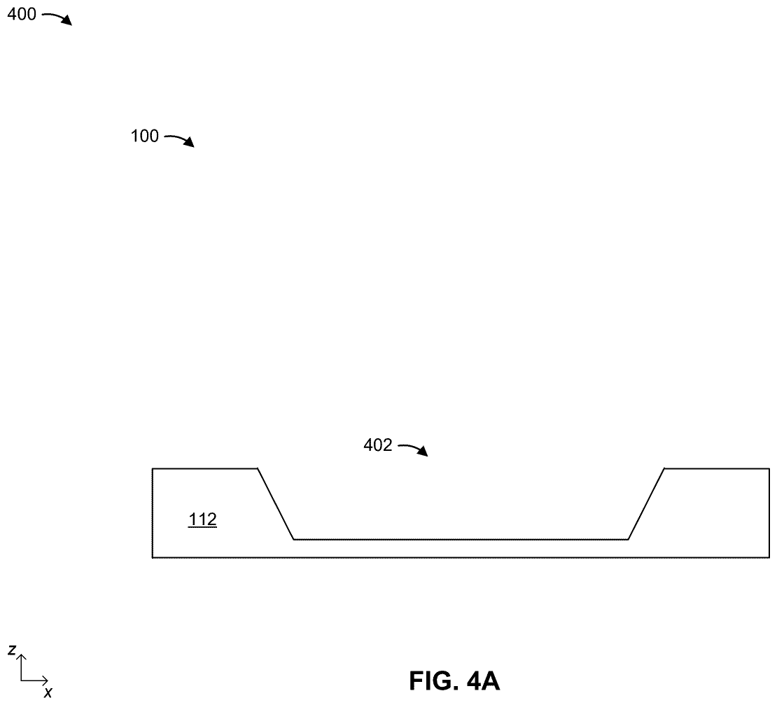

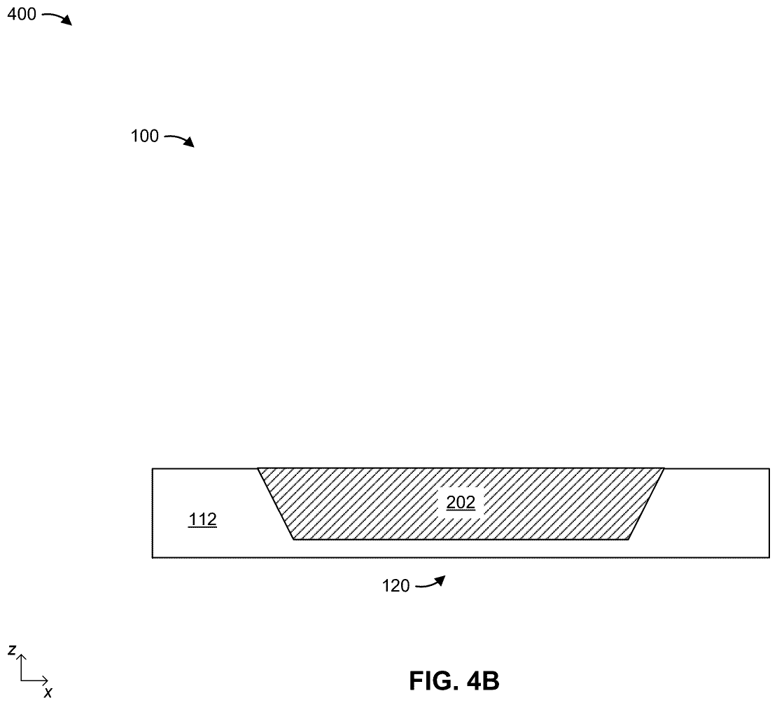

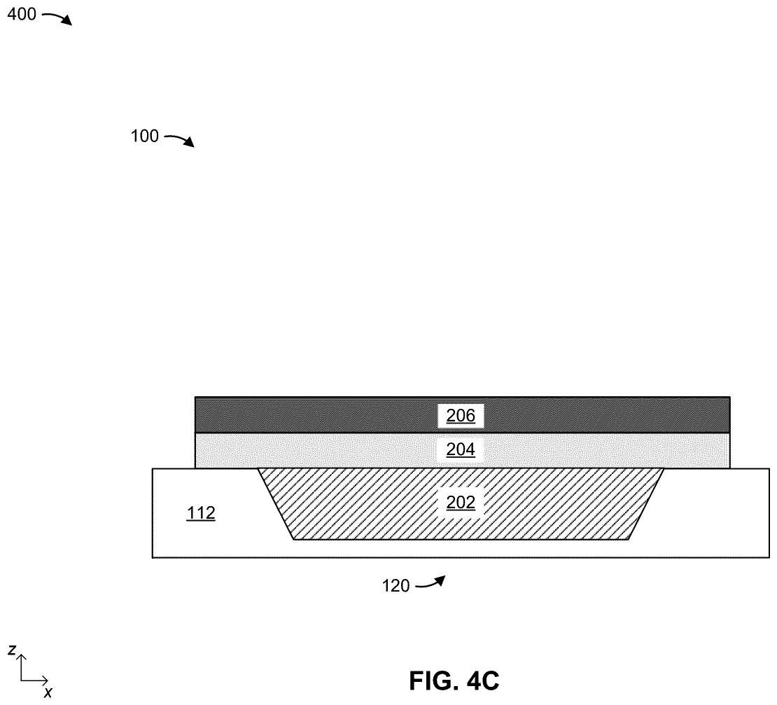

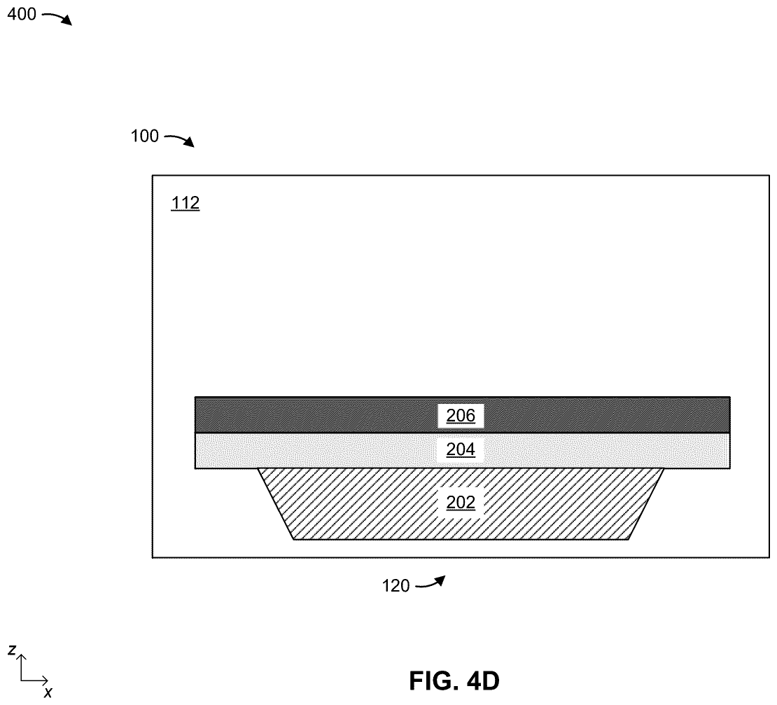

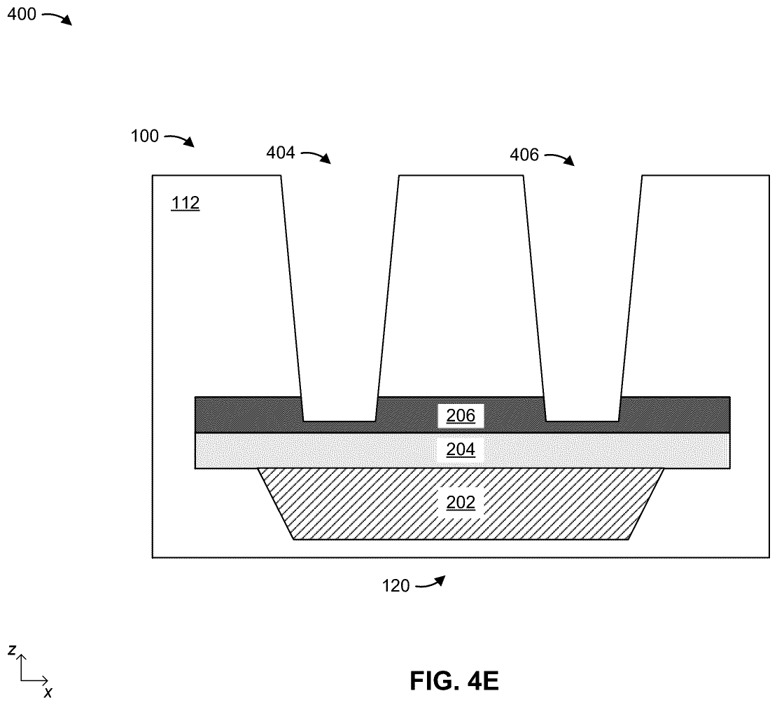

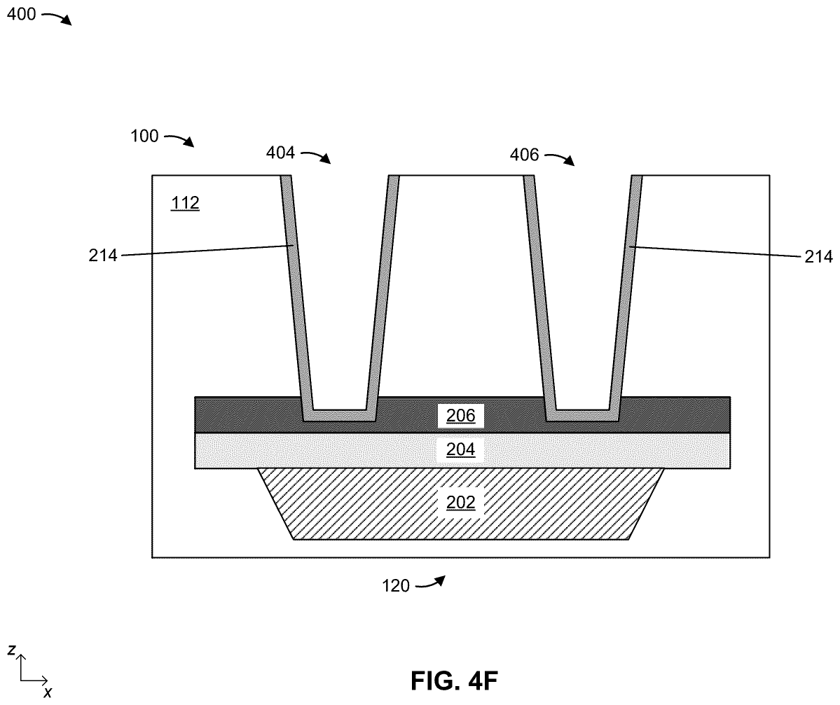

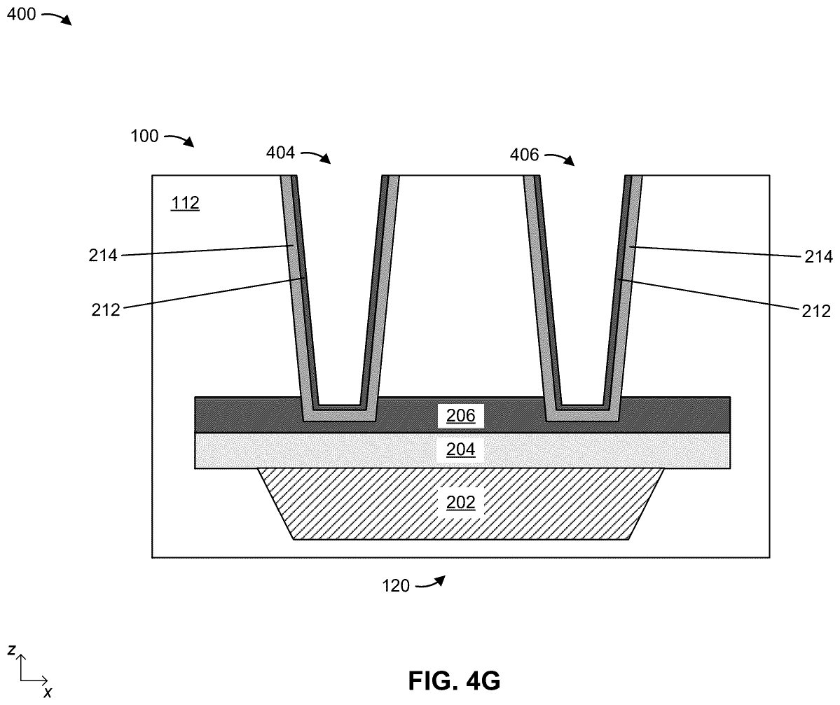

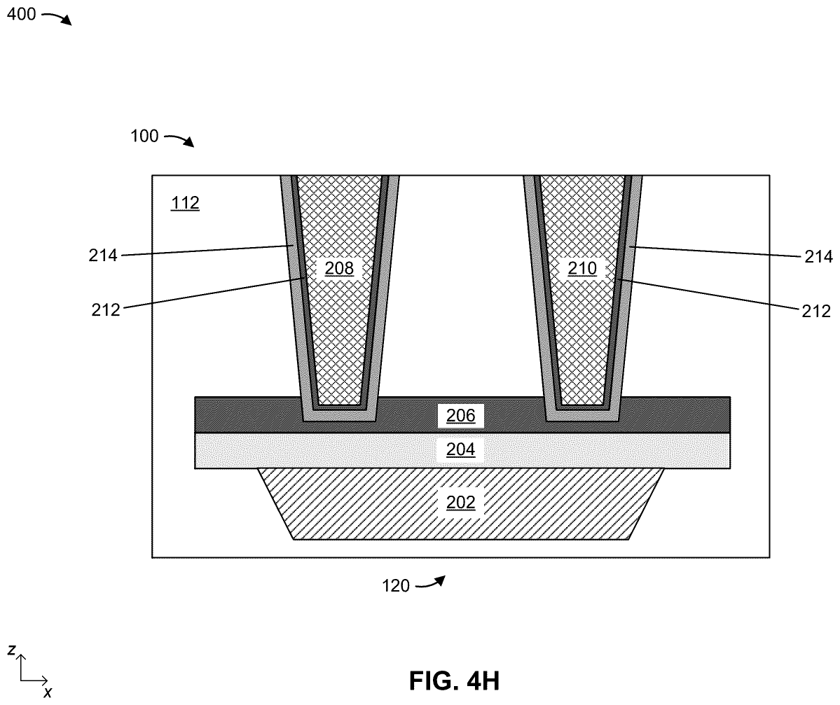

As shown in FIG. 3E, a second portion of the interconnect layer 104 of the semiconductor device 100 is formed over and/or on the first portion of the interconnect layer 104. Techniques similar to those described in connection with FIG. 3D may be performed to form the second portion of the interconnect layer 104. Additionally, a transistor structure 120 (e.g., a backend transistor structure or a BEOL transistor structure) is formed in an ILD layer 112 in the second portion of the interconnect layer 104. Conductive structures 116 may be formed on the transistor structure 120 to electrically connect the transistor structure 120 in the interconnect layer 104. An example implementation of forming the transistor structure 120 is illustrated and described in connection with FIGS. 4A-4H.

As shown in FIG. 3F, a third portion of the interconnect layer 104 may be formed above the second portion of the interconnect layer 104 that includes the transistor structure 120. The third portion of the interconnect layer 104 may be formed using a similar combination of techniques as described in connection with FIGS. 3D and 3E.

As further shown in FIG. 3F, the connection structures 118 are formed on the interconnect layer 104 such that the connection structures 118 are electrically coupled and/or physically coupled with one or more conductive structures 116 in the interconnect layer 104. A deposition tool may be used to deposit the connection structures 118 using a CVD technique, a PVD technique, an ALD technique, an electroplating technique, and/or a deposition technique other than as described above in connection with FIG. 1. In some implementations, a semiconductor packaging tool attaches the connection structures 118 to the semiconductor device 100.

As indicated above, FIGS. 3A-3F are provided as an example. Other examples may differ from what is described with regard to FIGS. 3A-3F.

FIGS. 4A-4H are diagrams of an example implementation 400 of forming the transistor structure 120 described herein. In some implementations, one or more of the semiconductor processing operations described in connection with FIGS. 4A-4H may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 4A, the operations described in the example implementation 400 may be performed in connection with an ILD layer 112 of the interconnect layer 104 of the semiconductor device 100. The operations described in the example implementation 400 may be performed in connection with forming the semiconductor device 100, as described in connection with FIGS. 3A-3F. For example, the operations described in the example implementation 400 may be performed in connection with forming the interconnect layer 104, as described in connection with FIG. 3E.

As further shown in FIG. 4A, a recess 402 may be formed in the ILD layer 112. In some implementations, a pattern in a photoresist layer is used to etch the ILD layer 112 to form the recess 402. In these implementations, a deposition tool may be used to form the photoresist layer on the ILD layer 112 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 112 based on the pattern to form the recess 402. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 112 based on a pattern.

As shown in FIG. 4B, the gate electrode 202 may be formed in the recess 402 in the ILD layer 112. A deposition tool may deposit the gate electrode 202 using a CVD technique, a PVD technique, an ALD technique, an electroplating technique, and/or another suitable deposition technique. In some implementations, a planarization tool may be used to perform a chemical mechanical planarization (CMP) operation to planarize the gate electrode 202 after the gate electrode 202 is deposited.

As shown in FIG. 4C, the gate dielectric layer 204 may be formed above and/or on the gate electrode 202A deposition tool may deposit the gate dielectric layer 204 using a CVD technique, a PVD technique, an ALD technique, an oxidation technique, and/or another suitable deposition technique. In some implementations, a planarization tool may be used to perform a CMP operation to planarize the gate dielectric layer 204 after the gate dielectric layer 204 is deposited.

As further shown in FIG. 4C, the oxide-semiconductor channel layer 206 is formed over and/or on the gate dielectric layer 204. A deposition tool may be used to deposit the oxide-semiconductor channel layer 206 using an ALD technique, a CVD technique, a PVD technique, and/or another suitable deposition technique. In some implementations, a planarization tool is used to perform a CMP operation to planarize the oxide-semiconductor channel layer 206 after the oxide-semiconductor channel layer 206 is deposited. The oxide-semiconductor channel layer 206 may be formed of a high electron concentration oxide-semiconductor material, as described in connection with FIGS. 2A and 2B.

As shown in FIG. 4D, additional material of the ILD layer 112 may be formed over and/or on the p-type oxide-semiconductor channel layer 06. Moreover, the additional material of the ILD layer 112 may be formed such that the transistor structure 120 is encapsulated by the ILD layer 112. A deposition tool may be used to deposit the additional material of the ILD layer 112 using an ALD technique, a CVD technique, a PVD technique, an oxidation technique, and/or another suitable deposition technique. In some implementations, a planarization tool is used to perform a CMP operation to planarize the ILD layer 112 after the additional material of the ILD layer 112 is deposited.

As shown in FIG. 4E, recesses 404 and 406 may be formed in and/or through the ILD layer 112 such that portions of the top surface of the oxide-semiconductor channel layer 206 are exposed through the recesses 404 and 406. In some implementations, the recesses 404 and 406 are formed such that the recesses 404 and 406 extend into a portion of the oxide-semiconductor channel 206 such that the bottom surfaces of the recesses 404 and 406 are below the top surface of the oxide-semiconductor channel 206.

In some implementations, a pattern in a photoresist layer is used to etch the ILD layer 112 to form the recesses 404 and 406. In these implementations, a deposition tool may be used to form the photoresist layer on the ILD layer 112. An exposure tool may be used to expose the photoresist layer to a radiation source to pattern the photoresist layer. A developer tool may be used to develop and remove portions of the photoresist layer to expose the pattern. An etch tool may be used to etch the ILD layer 112 based on the pattern to form the recesses 404 and 406 in the ILD layer 112. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 112 based on a pattern.

As shown in FIG. 4F, the oxide-semiconductor barrier layer 214 is formed in the recesses 404 and 406. The oxide-semiconductor barrier layer 214 may be deposited using a conformal deposition technique such as CVD and/or ALD, such that the oxide-semiconductor barrier layer 214 is a conformal layer that conforms to the profile of the recesses 404 and 406. The oxide-semiconductor barrier layer 214 may be deposited on the sidewalls and on the bottom surfaces of the recesses 404 and 406. In implementations in which the recesses 404 and 406 extend into a portion of the oxide-semiconductor channel layer 206, the oxide-semiconductor barrier layer 214 may be deposited directly on, and may extend into, the oxide-semiconductor channel layer 206 at the bottom of the recesses 404 and 406.

The oxide-semiconductor barrier layer 214 may be formed of a low electron concentration oxide-semiconductor material, as described in connection with FIGS. 2A and 2B. In this way, the electron concentration of the oxide-semiconductor barrier layer 214 is less than the electron concentration of the oxide-semiconductor channel layer 206.

As shown in FIG. 4G, the oxide-semiconductor barrier layer 212 may be formed on the oxide-semiconductor barrier layer 214 in the recesses 404 and 406. Alternatively, the oxide-semiconductor barrier layer 212 may be omitted from the transistor structure 120, such as in the example implementations illustrated in FIGS. 6 and 7. The oxide-semiconductor barrier layer 212 may be deposited using a conformal deposition technique such as CVD and/or ALD, such that the oxide-semiconductor barrier layer 212 is a conformal layer that conforms to the profile of the recesses 404 and 406. The oxide-semiconductor barrier layer 212 may be deposited on the sidewalls and on the bottom surfaces of the recesses 404 and 406.

The oxide-semiconductor barrier layer 212 may be formed of a high electron concentration oxide-semiconductor material, as described in connection with FIGS. 2A and 2B. In this way, the electron concentration of the oxide-semiconductor barrier layer 212 is greater than the electron concentration of the oxide-semiconductor barrier layer 214. In some implementations, the electron concentration of the oxide-semiconductor barrier layer 214 is approximately equal to the electron concentration of the oxide-semiconductor channel layer 206.

In some implementations, the oxide-semiconductor barrier layer 214, and the oxide-semiconductor channel layer 206 and the oxide-semiconductor barrier layer 212, are formed of a same oxide-semiconductor material that is doped and/or treated to have different concentrations of hydrogen (H), oxygen (O), and/or fluorine (F), among other examples. In some implementations, the oxide-semiconductor barrier layer 214, and the oxide-semiconductor channel layer 206 and the oxide-semiconductor barrier layer 212, are formed of different oxide-semiconductor materials that have different concentrations of hydrogen (H), oxygen (O), and/or fluorine (F), among other examples.

In some implementations, the oxide-semiconductor channel layer 206, the oxide-semiconductor barrier layer 212, and/or the oxide-semiconductor barrier layer 214 are formed such that the hydrogen (H) concentration in the oxide-semiconductor barrier layer 214 is less than the hydrogen concentrations in the oxide-semiconductor channel layer 206 and the oxide-semiconductor barrier layer 212. The greater hydrogen concentrations in the oxide-semiconductor channel layer 206 and the oxide-semiconductor barrier layer 212 may be achieved through hydrogen treatment of the oxide-semiconductor channel layer 206 and the oxide-semiconductor barrier layer 212. The hydrogen treatment may be in the form of the use of a hydrogen-rich deposition technique to form the oxide-semiconductor channel layer 206 and the oxide-semiconductor barrier layer 212. For example, a plasma-enhanced chemical vapor deposition (PECVD) technique, in which hydrogen-containing precursors are used, can be used to deposit the material of the oxide-semiconductor channel layer 206 and the oxide-semiconductor barrier layer 212 such that the material of the oxide-semiconductor channel layer 206 and the oxide-semiconductor barrier layer 212 has a high hydrogen concentration. Additionally and/or alternatively, a hydrogen-based plasma cleaning operation may be performed on the oxide-semiconductor channel layer 206 and/or on the oxide-semiconductor barrier layer 212 to increase the hydrogen concentration in the oxide-semiconductor channel layer 206 and/or on the oxide-semiconductor barrier layer 212.

In some implementations, the oxide-semiconductor channel layer 206, the oxide-semiconductor barrier layer 212, and/or the oxide-semiconductor barrier layer 214 are formed such that the oxygen (O) concentration in the oxide-semiconductor barrier layer 214 may be greater than the oxygen concentrations in the oxide-semiconductor channel layer 206 and the oxide-semiconductor barrier layer 212. Additionally and/or alternatively, the oxide-semiconductor channel layer 206, the oxide-semiconductor barrier layer 212, and/or the oxide-semiconductor barrier layer 214 are formed such that the fluorine (F) concentration in the oxide-semiconductor barrier layer 214 may be greater than the fluorine concentrations in the oxide-semiconductor channel layer 206 and the oxide-semiconductor barrier layer 212. The greater oxygen concentration and/or the greater fluorine concentration in the oxide-semiconductor barrier layer 214 may result in a lesser concentration of charge carrier vacancies in the oxide-semiconductor barrier layer 214 than in the oxide-semiconductor channel layer 206 and in the oxide-semiconductor barrier layer 212.

An oxygen treatment and/or a fluorine treatment may be performed on the oxide-semiconductor barrier layer 214 to drive out hydrogen from the oxide-semiconductor barrier layer 214, thereby reducing charge carrier vacancies in the oxide-semiconductor barrier layer 214. For example, an oxygen-based plasma treatment and/or a fluorine-based plasma treatment may be performed on the oxide-semiconductor barrier layer 214 to increase the oxygen concentration and/or to increase the fluorine concentration in the oxide-semiconductor barrier layer 214. As another example, the oxide-semiconductor barrier layer 214 may be soaked in an oxygen-rich solution (e.g., wet oxidation) to increase the oxygen concentration in the oxide-semiconductor barrier layer 214. As another example, the oxide-semiconductor barrier layer 214 may be formed using fluorine-containing precursors to increase the fluorine concentration in the oxide-semiconductor barrier layer 214.

As shown in FIG. 4H, the source/drain electrodes 208 and 210 are respectively formed in the recesses 404 and 406. The source/drain electrodes 208 and 210 may be formed on and in direct physical contact with the oxide-semiconductor barrier layer 212 in the recesses 404 and 406. Alternatively, the oxide-semiconductor barrier layer 212 may be omitted, and the source/drain electrodes 208 and 210 may be formed on and in direct physical contact with the oxide-semiconductor barrier layer 214 in the recesses 404 and 406.

The source/drain electrodes 208 and 210 may land on the portions of the oxide-semiconductor channel layer 206 that are exposed in the recesses 404 and 406 such that the source/drain electrodes 208 and 210 are electrically coupled and/or physically coupled with the oxide-semiconductor channel layer 206. In some implementations, the recesses 404 and 406 extend into a portion of the oxide-semiconductor channel layer 206 such that the source/drain electrodes 208 and 210 extend into the oxide-semiconductor channel layer 206.

A deposition tool may be used to deposit the source/drain electrodes 208 and 210 using a CVD technique, a PVD technique, an ALD technique, an electroplating technique, and/or another suitable deposition technique. In some implementations, a planarization tool may be used to planarize the top surfaces of the source/drain electrodes 208 and 210 after the source/drain electrodes 208 and 210 are deposited. The planarization of the source/drain electrodes 208 and 210 results in the top surfaces of the source/drain electrodes 208 and 210 and the top surface of the ILD layer 112 being substantially co-planar.

As indicated above, FIGS. 4A-4H are provided as an example. Other examples may differ from what is described with regard to FIGS. 4A-4H.

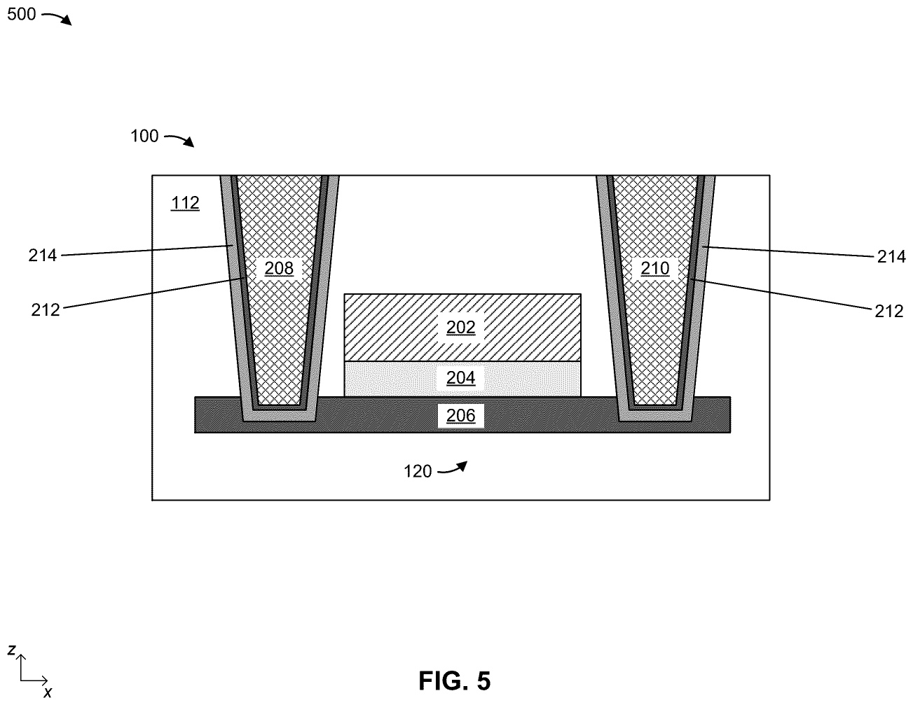

FIG. 5 is a diagram of an example implementation 500 of a transistor structure 120 described herein. As shown in FIG. 5, the example implementation 500 of the transistor structure 120 is similar to the example implementation 200 of the transistor structure 120 illustrated and described in connection with FIG. 2A. For example, the example implementation 500 of the transistor structure 120 in FIG. 5 includes the gate electrode 202, the gate dielectric layer 204, the oxide-semiconductor channel layer 206, the source/drain electrodes 208 and 210, and the oxide-semiconductor barrier layers 212 and 214.

However, the example implementation 500 of the transistor structure 120 in FIG. 5 includes a top gate electrode, as opposed to the bottom gate electrode in the example implementation 200 in FIG. 2A. Thus, in the example implementation 500 of the transistor structure 120 in FIG. 5, the gate dielectric layer 204 and the gate electrode 202 are included above the oxide-semiconductor channel layer 206, and the gate electrode 202 is included above the gate dielectric layer 204. The gate electrode 202 and the gate dielectric layer 204 are included between the source/drain electrodes 208 and 210. Thus, the gate electrode 202 and the gate dielectric layer 204 are located laterally between the portions of the oxide-semiconductor barrier layers 212 and 214 on the sidewalls of the source/drain electrodes 208 and 210, instead of the oxide-semiconductor channel layer 206 being located vertically between the gate electrode 202 and the portions of the oxide-semiconductor barrier layers 212 and 214 on the bottom surfaces of the source/drain electrodes 208 and 210.

As indicated above, FIG. 5 is provided as an example. Other examples may differ from what is described with regard to FIG. 5.

FIG. 6 is a diagram of an example implementation 600 of a transistor structure 120 described herein. As shown in FIG. 6, the example implementation 600 of the transistor structure 120 is similar to the example implementation 200 of the transistor structure 120 illustrated and described in connection with FIG. 2A. For example, the example implementation 600 of the transistor structure 120 in FIG. 6 includes the gate electrode 202, the gate dielectric layer 204, the oxide-semiconductor channel layer 206, the source/drain electrodes 208 and 210, and the oxide-semiconductor barrier layer 214.

However, in the example implementation 600 of the transistor structure 120 in FIG. 6, the oxide-semiconductor barrier layer 212 is omitted. Instead, the source/drain electrodes 208 and 210 are formed directly on (and in physical contact with) the oxide-semiconductor barrier layer 214 in the recesses 404 and 406, respectively. Omitting the oxide-semiconductor barrier layer 212, such as in the example implementation 600 of the transistor structure 120 in FIG. 6, may enable a lesser off current leakage to be achieved for the transistor structure 120. However, including the oxide-semiconductor barrier layer 212, such as in the example implementations 200 and 500 of the transistor structure 120, may enable lesser contact resistance and higher on current to be achieved for the transistor structure 120.

As indicated above, FIG. 6 is provided as an example. Other examples may differ from what is described with regard to FIG. 6.

FIG. 7 is a diagram of an example implementation 700 of a transistor structure 120 described herein. As shown in FIG. 7, the example implementation 700 of the transistor structure 120 is similar to the example implementation 600 of the transistor structure 120 illustrated and described in connection with FIG. 6. For example, the example implementation 700 of the transistor structure 120 in FIG. 7 includes the gate electrode 202, the gate dielectric layer 204, the oxide-semiconductor channel layer 206, the source/drain electrodes 208 and 210, and the oxide-semiconductor barrier layer 214 (e.g., the oxide-semiconductor barrier layer 212 being omitted).

However, the example implementation 700 of the transistor structure 120 in FIG. 7 includes a top gate electrode, as opposed to the bottom gate electrode in the example implementation 600 in FIG. 6. Thus, in the example implementation 700 of the transistor structure 120 in FIG. 7, the gate dielectric layer 204 and the gate electrode 202 are included above the oxide-semiconductor channel layer 206, and the gate electrode 202 is included above the gate dielectric layer 204. The gate electrode 202 and the gate dielectric layer 204 are included between the source/drain electrodes 208 and 210. Thus, the gate electrode 202 and the gate dielectric layer 204 are located laterally between the portions of the oxide-semiconductor barrier layer 214 on the sidewalls of the source/drain electrodes 208 and 210, instead of the oxide-semiconductor channel layer 206 being located vertically between the gate electrode 202 and the portions of the oxide-semiconductor barrier layer 214 on the bottom surfaces of the source/drain electrodes 208 and 210.

As indicated above, FIG. 7 is provided as an example. Other examples may differ from what is described with regard to FIG. 7.

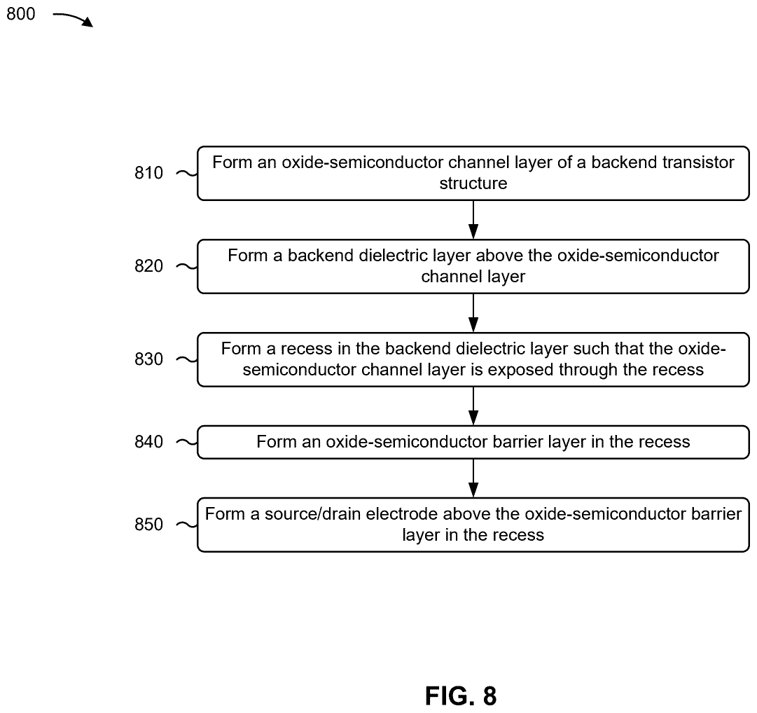

FIG. 8 is a flowchart of an example process 800 associated with forming a backend transistor structure described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include forming an oxide-semiconductor channel layer of a backend transistor structure (block 810). For example, one or more semiconductor processing tools may be used to form an oxide-semiconductor channel layer (e.g., an oxide-semiconductor channel layer 206) of a backend transistor structure (e.g., a transistor structure 120), as described herein.

As further shown in FIG. 8, process 800 may include forming a backend dielectric layer above the oxide-semiconductor channel layer (block 820). For example, one or more semiconductor processing tools may be used to form a backend dielectric layer (e.g., an ILD layer 112) above the oxide-semiconductor channel layer, as described herein.

As further shown in FIG. 8, process 800 may include forming a recess in the backend dielectric layer such that the oxide-semiconductor channel layer is exposed through the recess (block 830). For example, one or more semiconductor processing tools may be used to form a recess (e.g., a recess 404, a recess 406) in the backend dielectric layer such that the oxide-semiconductor channel layer is exposed through the recess, as described herein.

As further shown in FIG. 8, process 800 may include forming an oxide-semiconductor barrier layer in the recess (block 840). For example, one or more semiconductor processing tools may be used to form an oxide-semiconductor barrier layer (e.g., an oxide-semiconductor barrier layer 214) in the recess, as described herein. In some implementations, an oxygen concentration in the oxide-semiconductor barrier layer is greater than an oxygen concentration in the oxide-semiconductor channel layer.

As further shown in FIG. 8, process 800 may include forming a source/drain electrode above the oxide-semiconductor barrier layer in the recess (block 850). For example, one or more semiconductor processing tools may be used to form a source/drain electrode (e.g., a source/drain electrode 208, a source/drain electrode 210) above the oxide-semiconductor barrier layer in the recess, as described herein.

Process 800 may include additional implementations, such as any single implementation or any combination of implementations described below and/or in connection with one or more other processes described elsewhere herein.

In a first implementation, the recess extends into a portion of the oxide-semiconductor channel layer, and forming the oxide-semiconductor barrier layer includes forming the oxide-semiconductor barrier layer such that a portion of the oxide-semiconductor barrier layer, at a bottom of the recess, is included on the oxide-semiconductor channel layer.

In a second implementation, alone or in combination with the first implementation, forming the oxide-semiconductor barrier layer includes conformally depositing the oxide-semiconductor barrier layer on sidewalls of the recess and on a bottom surface of the recess.

In a third implementation, alone or in combination with one or more of the first and second implementations, forming the oxide-semiconductor barrier layer includes forming a first oxide-semiconductor barrier layer (e.g., the oxide-semiconductor barrier layer 214) in the recess, and the process 800 further includes forming a second oxide-semiconductor barrier layer (e.g., an oxide-semiconductor barrier layer 212) on the first oxide-semiconductor barrier layer in the recess, where an oxygen concentration in the second oxide-semiconductor barrier layer is less than the oxygen concentration in the first oxide-semiconductor barrier layer.

In a fourth implementation, alone or in combination with one or more of the first through third implementations, forming the source/drain electrode includes forming the source/drain electrode on the second oxide-semiconductor barrier layer in the recess.

In a fifth implementation, alone or in combination with one or more of the first through fourth implementations, forming the source/drain electrode includes forming the source/drain electrode directly on the oxide-semiconductor barrier layer in the recess.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a transistor structure (e.g., a backend transistor structure in an interconnect layer of a semiconductor device) is formed to include an oxide-semiconductor channel layer having a high electron concentration oxide-semiconductor material. The high electron concentration oxide-semiconductor material enables a low threshold voltage and a low channel resistance to be achieved for the oxide-semiconductor channel layer, which enables a high on current to be achieved for the transistor structure. To provide channel control over the oxide-semiconductor channel layer, an oxide-semiconductor barrier layer is included between the source/drain electrodes of the transistor structure and the oxide-semiconductor channel layer. The oxide-semiconductor barrier layer includes a low electron concentration oxide-semiconductor material, which enables increased control over the conductivity of the oxide-semiconductor channel layer to be achieved, which enables a low off current leakage to be achieved for the transistor structure.

As described in greater detail above, some implementations described herein provide a transistor structure. The transistor structure includes a gate electrode. The transistor structure includes an oxide-semiconductor channel layer. The transistor structure includes a gate dielectric layer vertically between the gate electrode and the oxide-semiconductor channel layer. The transistor structure includes a source/drain electrode coupled to the oxide-semiconductor channel layer. The transistor structure includes an oxide-semiconductor barrier layer between the oxide-semiconductor channel layer and the source/drain electrode, where an electron concentration in the oxide-semiconductor barrier layer is less than an electron concentration in the oxide-semiconductor channel layer.

As described in greater detail above, some implementations described herein provide a transistor structure. The transistor structure includes a gate electrode. The transistor structure includes an oxide-semiconductor channel layer. The transistor structure includes a gate dielectric layer vertically between the gate electrode and the oxide-semiconductor channel layer. The transistor structure includes a source/drain electrode coupled to the oxide-semiconductor channel layer. The transistor structure includes an oxide-semiconductor barrier layer between the oxide-semiconductor channel layer and the source/drain electrode, where a hydrogen concentration in the oxide-semiconductor channel layer is greater than a hydrogen concentration in the oxide-semiconductor barrier layer.

As described in greater detail above, some implementations described herein provide a method. The method includes forming an oxide-semiconductor channel layer of a backend transistor structure. The method includes forming a backend dielectric layer above the oxide-semiconductor channel layer. The method includes forming a recess in the backend dielectric layer such that the oxide-semiconductor channel layer is exposed through the recess. The method includes forming an oxide-semiconductor barrier layer in the recess, where an oxygen concentration in the oxide-semiconductor barrier layer is greater than an oxygen concentration in the oxide-semiconductor channel layer. The method includes forming a source/drain electrode above the oxide-semiconductor barrier layer in the recess.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor structure, comprising:
a gate electrode;
an oxide-semiconductor channel layer;
a gate dielectric layer vertically between the gate electrode and the oxide-semiconductor channel layer;
a source/drain electrode coupled to the oxide-semiconductor channel layer; and
an oxide-semiconductor barrier layer between the oxide-semiconductor channel layer and the source/drain electrode,
wherein an electron concentration in the oxide-semiconductor barrier layer is less than an electron concentration in the oxide-semiconductor channel layer.

2. The transistor structure of claim 1, wherein the oxide-semiconductor barrier layer is in direct physical contact with the source/drain electrode and is in direct physical contact with the oxide-semiconductor channel layer.

3. The transistor structure of claim 1, wherein the oxide-semiconductor barrier layer is a first oxide-semiconductor barrier layer in the transistor structure; and
wherein the transistor structure further comprises:
a second oxide-semiconductor barrier layer between the first oxide-semiconductor barrier layer and the source/drain electrode,
wherein an electron concentration in the second oxide-semiconductor barrier layer is greater than the electron concentration in the first oxide-semiconductor barrier layer.

4. The transistor structure of claim 3, wherein the second oxide-semiconductor barrier layer is located between sidewalls of the source/drain electrode and the first oxide-semiconductor barrier layer; and
wherein the second oxide-semiconductor barrier layer is located between a bottom surface of the source/drain electrode and the first oxide-semiconductor barrier layer.

5. The transistor structure of claim 1, wherein a thickness of the oxide-semiconductor barrier layer is greater than approximately 0 nanometers and less than approximately 10 nanometers.

6. The transistor structure of claim 1, wherein the oxide-semiconductor channel layer is vertically between the gate electrode and the oxide-semiconductor barrier layer.

7. The transistor structure of claim 1, wherein the oxide-semiconductor barrier layer is laterally between the gate electrode and the source/drain electrode.

8. The transistor structure of claim 1, wherein the electron concentration in the oxide-semiconductor barrier layer is included in a range of approximately 5×10¹⁶ electrons per cubic centimeter to approximately 1×10¹⁸ electrons per cubic centimeter; and
wherein the electron concentration in the oxide-semiconductor channel layer is included in a range of greater than approximately 1×10¹⁸ electrons per cubic centimeter and less than or approximately equal to 1×10²⁰ electrons per cubic centimeter.

9. A transistor structure, comprising:
a gate electrode;
an oxide-semiconductor channel layer;
a gate dielectric layer vertically between the gate electrode and the oxide-semiconductor channel layer;
a source/drain electrode coupled to the oxide-semiconductor channel layer; and
an oxide-semiconductor barrier layer between the oxide-semiconductor channel layer and the source/drain electrode,
wherein a hydrogen concentration in the oxide-semiconductor channel layer is greater than a hydrogen concentration in the oxide-semiconductor barrier layer.

10. The transistor structure of claim 9, wherein an oxygen concentration in the oxide-semiconductor barrier layer is greater than an oxygen concentration in the oxide-semiconductor channel layer.

11. The transistor structure of claim 9, wherein a fluorine concentration in the oxide-semiconductor barrier layer is greater than a fluorine concentration in the oxide-semiconductor channel layer.

12. The transistor structure of claim 9, wherein the oxide-semiconductor barrier layer is in direct physical contact with the source/drain electrode and is in direct physical contact with the oxide-semiconductor channel layer.

13. The transistor structure of claim 9, wherein the oxide-semiconductor barrier layer is a first oxide-semiconductor barrier layer in the transistor structure; and
wherein the transistor structure further comprises:
a second oxide-semiconductor barrier layer between the first oxide-semiconductor barrier layer and the source/drain electrode,
wherein a hydrogen concentration in the second oxide-semiconductor barrier layer is greater than the hydrogen concentration in the first oxide-semiconductor barrier layer.

14. The transistor structure of claim 9, wherein a portion of the oxide-semiconductor barrier layer at a bottom of the source/drain electrode is recessed in the oxide-semiconductor channel layer.

15. A method, comprising:
forming an oxide-semiconductor channel layer of a backend transistor structure;
forming a backend dielectric layer above the oxide-semiconductor channel layer;
forming a recess in the backend dielectric layer such that the oxide-semiconductor channel layer is exposed through the recess;
forming an oxide-semiconductor barrier layer in the recess,
wherein an oxygen concentration in the oxide-semiconductor barrier layer is greater than an oxygen concentration in the oxide-semiconductor channel layer; and
forming a source/drain electrode above the oxide-semiconductor barrier layer in the recess.

16. The method of claim 15, wherein the recess extends into a portion of the oxide-semiconductor channel layer; and
wherein forming the oxide-semiconductor barrier layer comprises:
forming the oxide-semiconductor barrier layer such that a portion of the oxide-semiconductor barrier layer, at a bottom of the recess, is included on the oxide-semiconductor channel layer.

17. The method of claim 15, wherein forming the oxide-semiconductor barrier layer comprises:
conformally depositing the oxide-semiconductor barrier layer on sidewalls of the recess and on a bottom surface of the recess.

18. The method of claim 15, wherein forming the oxide-semiconductor barrier layer comprises:
forming a first oxide-semiconductor barrier layer in the recess; and
wherein the method further comprises:
forming a second oxide-semiconductor barrier layer on the first oxide-semiconductor barrier layer in the recess,
wherein an oxygen concentration in the second oxide-semiconductor barrier layer is less than the oxygen concentration in the first oxide-semiconductor barrier layer.

19. The method of claim 18, wherein forming the source/drain electrode comprises:
forming the source/drain electrode on the second oxide-semiconductor barrier layer in the recess.

20. The method of claim 15, wherein forming the source/drain electrode comprises:
forming the source/drain electrode directly on the oxide-semiconductor barrier layer in the recess.
